(19) United States
(12) Patent Application Publication
(10) Pub. No.: US 2014/0312503 A1
(43) Pub. Date: Oct. 23, 2014

(54) SEMICONDUCTOR PACKAGES AND METHODS OF FABRICATING THE SAME

(71) Applicant: ByoungRim Seo, Hwaseong-si (KR)

(72) Inventor: ByoungRim Seo, Hwaseong-si (KR)

(21) Appl. No.: 14/100,503

(22) Filed: Dec. 9, 2013

(30) Foreign Application Priority Data
Apr. 23, 2013 (KR) 1020130044968

(51) Int. Cl. H01L 23/48; H01L 27/146

(52) U.S. Cl. CPC H01L 23/481; H01L 27/14636
USPC 257/774

(57) ABSTRACT

A semiconductor package comprises a package substrate including a package pad, the package pad being conductive. A semiconductor chip is on the package substrate including a chip pad, the chip pad being conductive, the semiconductor chip extending in a horizontal direction of extension. A transparent substrate is on the semiconductor chip. An insulative layer is at sides of the transparent substrate and on the package substrate. A vertical interconnect is through the insulative layer, the vertical interconnect in contact with at least one of the package pad and chip pad, the vertical interconnect extending in a substantially vertical direction of extension relative to the horizontal direction of extension of the semiconductor chip.

### CROSS-REFERENCE TO RELATED APPLICATIONS

This U.S. non-provisional patent application claims priority under 35 U.S.C. §119 to Korean Patent Application No. 10-2013-0044968, filed on Apr. 23, 2013, in the Korean Intellectual Property Office, the entire content of which is hereby incorporated by reference.

### BACKGROUND

Example embodiments of the inventive concepts relate to semiconductor devices, and, in particular, to semiconductor packages and methods of fabricating the same.

Image sensors, such as CCD or CMOS image sensors, are enjoying widespread use in various electronic products, such as mobile phones, digital cameras, optical mice, security cameras, and biometric devices. As electronic products become more highly integrated and ever-more multifunctional, there is an increasing demand for improved technical properties such as smaller size, higher density, lower power, multifunctional operation, higher speed signal-processing, higher reliability, lower cost, and clearer image quality, all in a semiconductor package containing an image sensor. Various research is being conducted to meet this demand.

### SUMMARY

Example embodiments of the inventive concepts provide a semiconductor package with improved signal routability and increased integration density.

Other example embodiments of the inventive concepts provide a method of fabricating a highly integrated semiconductor package with improved routability and increased integration density.

In an aspect, a semiconductor package comprises: a package substrate including a package pad, the package pad being conductive, a semiconductor chip on the package substrate including a chip pad, the chip pad being conductive, the semiconductor chip extending in a horizontal direction of extension; a transparent substrate on the semiconductor chip; an insulative layer at sides of the transparent substrate and on the package substrate; and a vertical interconnect through the insulative layer, the vertical interconnect in contact with at least one of the package pad and chip pad, the vertical interconnect extending in a substantially vertical direction of extension relative to the horizontal direction of extension of the semiconductor chip.

In some embodiments, the semiconductor package further comprises a redistribution pattern on the insulative layer and in contact with an upper portion of the vertical interconnect.

In some embodiments, a top of the insulative layer is lower in height relative to the package substrate than a top of the transparent substrate.

In some embodiments, a top portion of the vertical interconnect is greater in height relative to the package substrate than the top of the insulative layer.

In some embodiments, the semiconductor package further comprises a solder ball about the top portion of the vertical interconnect and on the insulative layer.

In some embodiments, the vertical interconnect comprises a conductive via.

In some embodiments, the vertical interconnect comprises a bonding wire.

In some embodiments, the bonding wire has a base at a direct contact portion that is wider than a top portion thereof.

In some embodiments, portions of the mold layer are positioned between the transparent substrate and the semiconductor chip.

In some embodiments, the semiconductor package further comprises adhesive layer portions between the transparent substrate and the semiconductor chip.

In some embodiments, the adhesive layer portions are positioned at corners of the transparent substrate between the transparent substrate and the semiconductor chip.

In some embodiments, the adhesive layer portions are positioned at edges of the transparent substrate between the transparent substrate and the semiconductor chip.

In some embodiments, the vertical interconnect is in direct contact with the chip pad.

In some embodiments, the vertical interconnect comprises multiple vertical interconnects positioned at corners of the semiconductor chip and in direct contact with multiple corresponding chip pads.

In some embodiments, the vertical interconnect is in direct contact with the package pad.

In some embodiments, the vertical interconnect comprises multiple vertical interconnects in direct contact with multiple corresponding package pads.

In some embodiments, the multiple corresponding package pads in direct contact with the multiple vertical interconnects are positioned to alternate with multiple other corresponding package pads that are in direct contact with chip pads via bonding wires.

In some embodiments, the semiconductor package further comprises a bonding wire that extends between the package pad and the chip pad and wherein a portion of the bonding wire is exposed above a top portion of the insulative layer.

In some embodiments, the insulative layer comprises a package mold layer

In some embodiments, the semiconductor package further comprises an autofocus module mounted on the transparent substrate opposite the package substrate, the autofocus module including conductive contacts electrically connected to the vertical interconnect, the autofocus module having a maximum outer width that is less than a maximum outer width of the package substrate.

In another aspect, a semiconductor package comprises: a package substrate including a package pad, the package pad being conductive; a semiconductor chip on the package substrate including a chip pad, the chip pad being conductive; a transparent substrate on the semiconductor chip; an insulative layer at sides of the transparent substrate and on the package substrate; and an interconnect through the insulative layer, the interconnect in contact with at least one of the package pad and chip pad and spaced apart from the transparent substrate, the interconnect extending to a top of the insulative layer.

In some embodiments, a portion of the interconnect extends above a top of the insulative layer.

In some embodiments, a portion of the insulative layer lies between the interconnect and the transparent substrate

In some embodiments, the semiconductor chip extends in a horizontal direction of extension and wherein the interconnect extends in a substantially vertical direction of extension relative to the horizontal direction of extension of the semiconductor chip.

In some embodiments, the semiconductor package further comprises a redistribution pattern on the insulative layer and in contact with an upper portion of the interconnect.

In some embodiments, a top of the insulative layer is lower in height relative to the package substrate than a top of the transparent substrate.

In some embodiments, a top portion of the interconnect is greater in height relative to the package substrate than the top of the insulative layer.

In some embodiments, the semiconductor package further comprises a solder ball about the top portion of the interconnect and on the insulative layer.

In some embodiments, the interconnect comprises a conductive via.

In some embodiments, the interconnect comprises a bonding wire.

In some embodiments, the bonding wire has a base at a direct contact portion that is wider than a top portion thereof.

In some embodiments, portions of the mold layer are positioned between the transparent substrate and the semiconductor chip.

In some embodiments, the semiconductor package further comprises adhesive layer portions between the transparent substrate and the semiconductor chip.

In some embodiments, the adhesive layer portions are positioned at corners of the transparent substrate between the transparent substrate and the semiconductor chip.

In some embodiments, the adhesive layer portions are positioned at edges of the transparent substrate between the transparent substrate and the semiconductor chip.

In some embodiments, the interconnect is in direct contact with the chip pad.

In some embodiments, the interconnect comprises multiple interconnects positioned at corners of the semiconductor chip and in direct contact with multiple corresponding chip pads.

In some embodiments, the interconnect is in direct contact with the package pad.

In some embodiments, the interconnect comprises multiple interconnects in direct contact with multiple corresponding package pads.

In some embodiments, the multiple corresponding package pads in direct contact with the multiple interconnects are positioned to alternate with multiple other corresponding package pads that are in direct contact with chip pads via bonding wires.

In some embodiments, the semiconductor package further comprises a bonding wire that extends between the package pad and the chip pad and wherein a portion of the bonding wire is exposed above a top portion of the insulative layer.

In some embodiments, the insulative layer comprises a package mold layer

In some embodiments, the semiconductor package further comprises an autofocus module mounted on the transparent substrate opposite the package substrate, the autofocus module including conductive contacts electrically connected to the interconnect, the autofocus module having a maximum outer width that is less than a maximum outer width of the package substrate.

In another aspect, a semiconductor package, comprises: a package substrate including a package pad, the package pad being conductive, the package substrate extending in a horizontal direction of extension, the package substrate having a width in the horizontal direction; a semiconductor chip on the package substrate including a chip pad, the chip pad being conductive; a transparent substrate on the semiconductor chip; an insulative layer at sides of the transparent substrate and on the package substrate; and an optical unit on the insulative layer and on the transparent substrate, the optical unit having a width in the horizontal direction that is less than or equal to the width of the package substrate.

In some embodiments, the optical unit has terminals that connect with terminals on the insulative layer, and wherein a distance between the terminals in the horizontal direction is less than the width of the package substrate in the horizontal direction.

In another aspect, a method for manufacturing a semiconductor device comprises: providing a semiconductor chip including an image sensor on a package substrate; providing a transparent substrate on the semiconductor chip; providing an insulative layer on the substrate, on the semiconductor chip and on the transparent substrate; and removing an upper portion of the insulative layer and an upper portion of the transparent substrate.

In some embodiments, the method further comprises providing a vertical in contact with at least one of a package pad on the package substrate and a chip pad on the semiconductor chip, the vertical interconnect extending in a substantially vertical direction of extension relative to a horizontal direction of extension of the semiconductor chip.

In some embodiments, providing the vertical interconnect is performed prior to providing the insulative layer on the substrate.

In some embodiments, providing the vertical interconnect is performed following providing the insulative layer on the substrate.

In some embodiments, the method further comprises, following removing an upper portion of the insulative layer and an upper portion of the transparent substrate, applying a conductive redistribution pattern to a top of the insulative layer and in electrical contact with the vertical interconnect.

In some embodiments, removing comprises at least one of a chemical mechanical polishing (CMP) process or a grinding process.

In another aspect, a semiconductor package comprises: a package substrate including a plurality of package pads, the package pads being conductive; a semiconductor chip on the package substrate including a plurality of chip pads, the chip pads being conductive; a transparent substrate on the semiconductor chip; an insulative layer at sides of the transparent substrate and on the package substrate; a plurality of bonding wires, each bonding wire connected between one of the chip pads and a corresponding one of the package pads; and a plurality of interconnects through the insulative layer, each interconnect in contact with at least one of the package pads and chip pads, wherein the interconnects comprise a material that is different than the bonding wires.

In some embodiments, the plurality of interconnects are spaced apart from the transparent substrate.

In some embodiments, the plurality of interconnects extend to a top of the insulative layer

In some embodiments, a portion of the interconnect extends above a top of the insulative layer.

In some embodiments, a portion of the insulative layer lies between the interconnect and the transparent substrate

In some embodiments, the semiconductor chip extends in a horizontal direction of extension and wherein the interconnect extends in a substantially vertical direction of extension relative to the horizontal direction of extension of the semiconductor chip.

In some embodiments, the semiconductor package further comprises a redistribution pattern on the insulative layer and in contact with an upper portion of the interconnect.

In some embodiments, a top of the insulative layer is lower in height relative to the package substrate than a top of the transparent substrate.

In some embodiments, a top portion of the interconnect is greater in height relative to the package substrate than the top of the insulative layer.

In some embodiments, the semiconductor package further comprises a solder ball about the top portion of the interconnect and on the insulative layer.

In some embodiments, the interconnect comprises a conductive via.

In some embodiments, the interconnect has a base at a direct contact portion that is narrower than a top portion thereof.

In some embodiments, portions of the mold layer are positioned between the transparent substrate and the semiconductor chip.

In some embodiments, the semiconductor package further comprises adhesive layer portions between the transparent substrate and the semiconductor chip.

In some embodiments, the adhesive layer portions are positioned at corners of the transparent substrate between the transparent substrate and the semiconductor chip.

In some embodiments, the adhesive layer portions are positioned at edges of the transparent substrate between the transparent substrate and the semiconductor chip.

In some embodiments, the interconnect is in direct contact with the chip pad.

In some embodiments, the interconnect comprises multiple interconnects positioned at corners of the semiconductor chip and in direct contact with multiple corresponding chip pads.

In some embodiments, the interconnect is in direct contact with the package pad.

In some embodiments, the interconnect comprises multiple interconnects in direct contact with multiple corresponding package pads.

In some embodiments, the multiple corresponding package pads in direct contact with the multiple interconnects are positioned to alternate with multiple other corresponding package pads that are in direct contact with chip pads via bonding wires.

In some embodiments, the insulative layer comprises a package mold layer

In some embodiments, the semiconductor package further comprises an autofocus module mounted on the transparent substrate opposite the package substrate, the autofocus module including conductive contacts electrically connected to the interconnect, the autofocus module having a maximum outer width that is less than a maximum outer width of the package substrate.

According to example embodiments of the inventive concepts, a semiconductor package may include a package substrate including a substrate connection terminal, a semiconductor chip including a chip connection terminal, on the package substrate, a transparent substrate on the semiconductor chip, a mold layer covering a side surface of the transparent substrate, the chip connection terminal, and the substrate connection terminal, and a first interconnection penetrating the mold layer to be in contact with at least one of the substrate and chip connection terminals, the first interconnection being spaced apart from the transparent substrate.

In example embodiments, the first interconnection may be provided using a wire bonding technique. Here, the first interconnection has a bottom width that may be greater than a top width thereof. In example embodiments, the first interconnection may be made of a metal, such as gold or copper.

In other example embodiments, the first interconnection may be a through-silicon via, and a bottom width of the first interconnection may be equivalent to or smaller than a top width thereof.

The semiconductor package may further include a second interconnection connecting the substrate connection terminal to the chip connection terminal. The second interconnection may be provided using a wire bonding technique. The first and second interconnections may be connected in common to the substrate connection terminal or the chip connection terminal. Alternatively, the second interconnection may be provided spaced apart from the substrate connection terminal or the chip connection terminal, which may be in contact with the first interconnection, to connect the substrate connection terminal to the chip connection terminal.

In certain embodiments, the first interconnection may be provided to connect the substrate connection terminal to the chip connection terminal and may include a top portion that may be located at a level equivalent to or higher than a top surface of the mold layer but may be formed in such a way that there may be not space between the first interconnection and the mold layer.

In example embodiments, the first interconnection has a top surface that may be coplanar with or protruded from that of the transparent substrate.

In example embodiments, the mold layer has a top surface that may be coplanar with or lower than that of the transparent substrate.

In example embodiments, the transparent substrate exposes an edge area of the package substrate.

The semiconductor package may further include an adhesive layer interposed between at least corners of the transparent substrate and the semiconductor chip. In example embodiments, the mold layer extends between the transparent substrate and the semiconductor chip. Alternatively, the adhesive layer may be provided along a lower edge of the transparent substrate to seal hermetically a space between the transparent substrate and the semiconductor chip.

In example embodiments, the semiconductor package may further include a redistribution pattern provided on the mold layer to be in contact with the first interconnection.

In example embodiments, the semiconductor package may further include an optical unit provided on the semiconductor transparent substrate and electrically connected to the first interconnection.

In example embodiments, the semiconductor package may further include a circuit substrate interposed between the optical unit and the transparent substrate and electrically connected to the first interconnection.

In example embodiments, the first interconnection, the mold layer, and the transparent substrate have top surfaces that may be coplanar with each other.

According to example embodiments of the inventive concepts, a method of fabricating a semiconductor package may include mounting a semiconductor chip with a chip connection terminal on a package substrate with a substrate connection terminal, attaching a transparent substrate on the semiconductor chip, forming a first interconnection on at least one of the substrate and chip connection terminals, and forming a mold layer to cover side surfaces of the first interconnection, the substrate and chip connection terminals, and the transparent substrate. The mold layer may be formed to expose a top portion of the first interconnection.

In example embodiments, the forming of the first interconnection may be accomplished using a wire bonding technique.

In example embodiments, the method may further include a polishing process to remove partially upper portions of the mold layer, the first interconnection, and the transparent substrate.

In example embodiments, the method may further include forming a second interconnection connecting the substrate connection terminal with the chip connection terminal.

In example embodiments, the first interconnection and the second interconnection may be formed in such a way that both of them may be connected in common to one of the substrate and chip connection terminals.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view illustrating a semiconductor package according to a first embodiment of the inventive concepts.

FIG. 2 is a sectional view taken along a line A-A of FIG. 1.

FIG. 3 is a sectional view of an electronic device including the semiconductor package of FIG. 2.

FIGS. 4 through 9 are sectional views sequentially illustrating a process of fabricating the semiconductor package of FIG. 2, in accordance with embodiments of the inventive concepts.

FIG. 10 is a sectional view illustrating a semiconductor package according to a second embodiment of the inventive concepts.

FIG. 11 is a sectional view of an electronic device including the semiconductor package of FIG. 10.

FIG. 12 is a sectional view illustrating a process of fabricating the semiconductor package of FIG. 10, in accordance with embodiments of the inventive concepts.

FIG. 13 is a sectional view illustrating a semiconductor package according to a third embodiment of the inventive concepts.

FIG. 14 is a plan view illustrating a semiconductor package according to a fourth embodiment of the inventive concepts.

FIG. 15 is a sectional view taken along a line A-A of FIG. 14.

FIG. 16 is a plan view illustrating a semiconductor package according to a fifth embodiment of the inventive concepts.

FIG. 17 is a sectional view taken along line A-A of FIG. 16.

FIG. 18A is a plan view illustrating a semiconductor package according to a sixth embodiment of the inventive concepts.

FIGS. 18B and 18C are sectional views taken along lines A-A and B-B of FIG. 18A, respectively.

FIGS. 19A and 19B are sectional views illustrating a process of fabricating the semiconductor package of FIG. 18B.

FIG. 20 is a plan view illustrating a semiconductor package according to a seventh embodiment of the inventive concepts.

FIGS. 21A and 21B are sectional views taken along lines A-A and C-C of FIG. 20, respectively.

FIG. 22 is a plan view illustrating a semiconductor package according to an eighth embodiment of the inventive concepts.

FIG. 23 is a plan view illustrating a semiconductor package according to a ninth embodiment of the inventive concepts.

FIG. 24 is a sectional view taken along a line A-A of FIG. 23.

FIG. 25A is a plan view illustrating a semiconductor package according to a tenth embodiment of the inventive concepts.

FIG. 25B is a sectional view taken along line A-A of FIG. 25A.

FIG. 25C is a sectional view of an electronic device with a semiconductor package of FIG. 25B.

FIGS. 26 through 30 show examples of multimedia devices, for which semiconductor package devices according to example embodiments of the inventive concepts can be employed.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

### First Embodiment

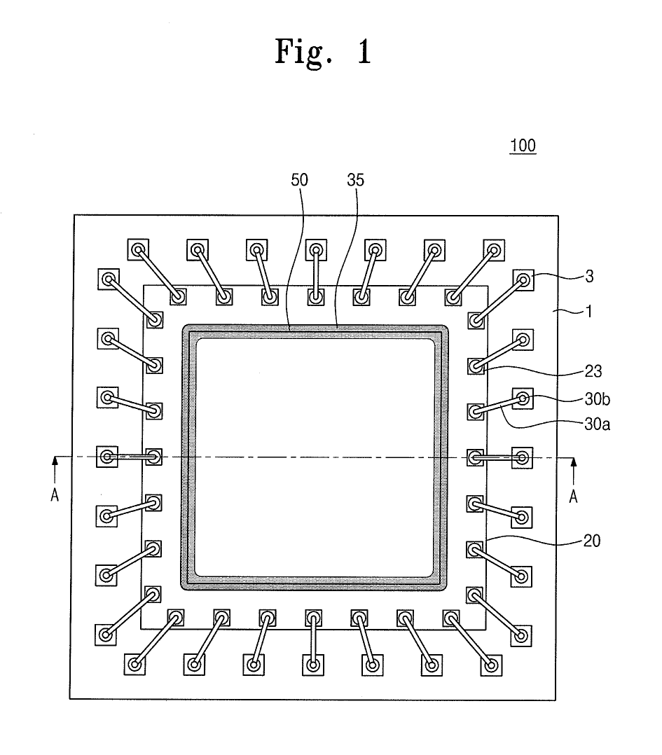

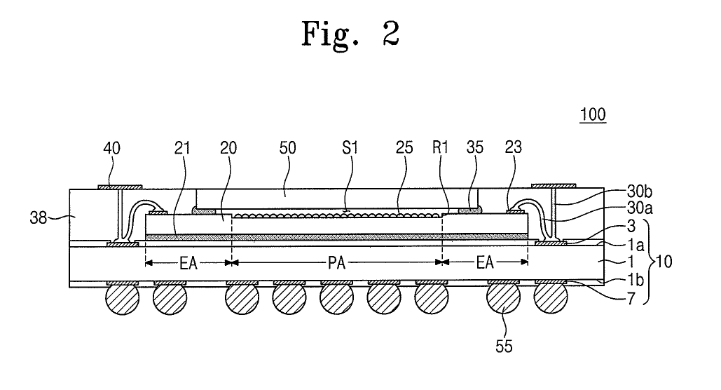

FIG. 1 is a plan view illustrating a semiconductor package according to a first embodiment of the inventive concepts. FIG. 2 is a sectional view taken along a line A-A of FIG. 1.

Referring to FIGS. 1 and 2, a semiconductor package 100 according to the first embodiment may include a semiconductor chip 20 mounted on a package substrate 10. The package substrate 10 may include a substrate body 1 having an opposed first surface 1a and second surface 1b. The semiconductor chip 20 may be applied to the first surface 1a by a first adhesive layer 21 interposed therebetween. For example, in some embodiments, the first adhesive layer 21 may comprise double-sided tape, or other suitable bonding material. In some embodiments, the substrate body 1 may comprise at least one of various insulating materials, such as plastic or ceramics. One or more conductive vias or one or more conductive circuit patterns may be provided in the substrate body 1. A first substrate connection terminal 3 may be provided on the first surface 1a, and a second substrate connection terminal 7 may be provided on the second surface 1b. The first substrate connection terminal 3 may comprise a conductive material and is otherwise referred to herein in some example embodiments as a “package pad”.

The first surface 1a and the second surface 1b may be covered with protection layers, respectively. A solder bump 55 may be attached to the second substrate connection terminal 7 of the package substrate 10.

The semiconductor chip 20 may include multiple defined areas, such as a pixel area PA and an edge area EA. In example embodiments, the semiconductor chip 20 may be an image sensor chip. Although not shown, a plurality of photoelectric conversion parts and a plurality of transistors, which are configured to deliver and process signals to be transmitted from the photoelectric conversion parts, may be provided in the pixel area PA of the semiconductor chip 20. A recess region R1 may be provided in the pixel area PA, and a micro lens array 25 may be provided within the recess region R1. Peripheral circuits may be provided in the edge area EA. A chip connection terminal 23 may be provided on the edge area EA of the semiconductor chip 20. The chip connection terminal 23 may comprise a conductive material and is otherwise referred to herein in some example embodiments as a “chip pad”.

A transparent substrate 50 may be provided to cover, or otherwise be positioned on, at least the pixel area PA of the semiconductor chip 20. In example embodiments, the transparent substrate 50 may have a width that is smaller than that of the semiconductor chip 20. The transparent substrate 50 may expose the chip connection terminal 23 and a portion of the edge area EA. A second adhesive layer 35 may be interposed between edges of the transparent substrate 50 and the semiconductor chip 20. A space S1 between the transparent substrate 50 and the semiconductor chip 20 may be hermetically sealed by the second adhesive layer 35.

The chip connection terminal 23 and the first substrate connection terminal 3 may be electrically connected to each other by a first interconnection 30a. A mold layer 38 may be provided to cover a sidewall of the transparent substrate 50, a portion of the edge area EA of the semiconductor chip 20, and a portion of the package substrate 10. A second interconnection 30b may be connected to the first substrate connection terminal 3 through the mold layer 38. The first interconnection 30a and the second interconnection 30b may be connected in common to a specific one of the first substrate connection terminal 3. In example embodiments, the first interconnection 30a and the second interconnection 30b may be connected to each other to form a single body. The first interconnection 30a and the second interconnection 30b may be metal wires (e.g., of gold or copper), which may be formed by a wire bonding process.

The second interconnection 30b, the mold layer 38 and the transparent substrate 50 may have top surfaces that are flat and coplanar with each other. A redistribution pattern 40 may be provided on the mold layer 38 and be connected to the second interconnection 30b. In some embodiments the second interconnection 30b may be oriented to extend in a substantially vertical direction. In some embodiments, the body of the first interconnection 30a or the body of the second interconnection 30b, or both, may be spaced apart from the transparent substrate 50, as shown in FIG. 2.

In the semiconductor package 100 according to the first embodiment, the second interconnection 30b may be formed using a simple wire bonding process, and thus, the semiconductor package 100 can be configured to have improved routability.

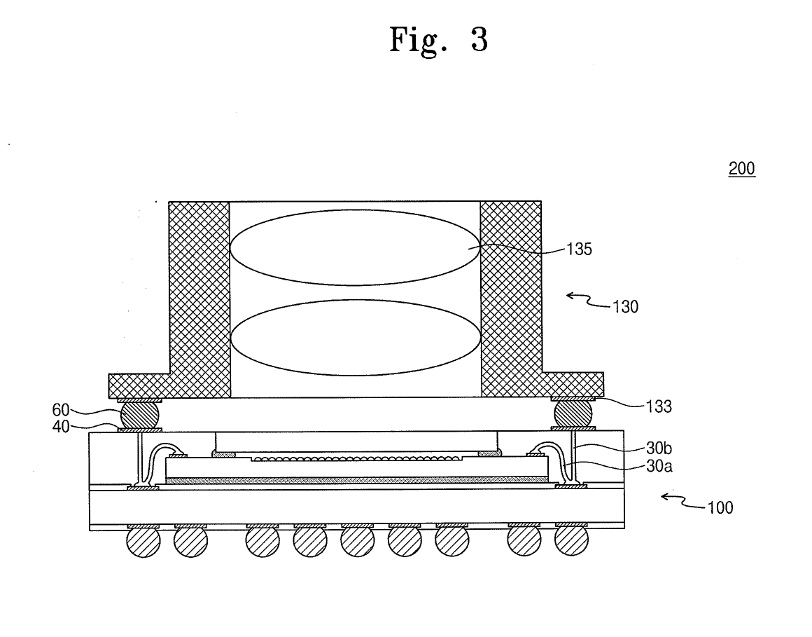

FIG. 3 is a sectional view of an electronic device including the semiconductor package of FIG. 2.

Referring to FIG. 3, in the electronic device 200, an optical unit 130 may be provided on the semiconductor package 100 of FIG. 2. A unit connection terminal 133 may be provided below the optical unit 130. A solder bump 60 may be interposed between the redistribution pattern 40 of the semiconductor package 100 and the unit connection terminal 133. The optical unit 130 may be configured to include a plurality of lenses 135. The semiconductor package 100 may be electrically connected to the optical unit 130 via the second interconnection 30b. The semiconductor package 100 may be configured to generate and provide electrical signals for operating the optical unit 130. The optical unit 130 may be configured to adjust positions of the lenses 135, thereby controlling a focal length thereof to control the direction of energy to the pixel area PA.

In various embodiments, the semiconductor package 100 may be connected to the optical unit 130 using not only the solder bump 60 but also by solder paste or other conductive bumps. According to example embodiments of the inventive concepts, the second interconnection 30b may be used to connect directly, in a generally vertical orientation, the semiconductor package 100 with the optical unit 130, and thus, it is possible to reduce a total size of the electronic device 200 including the optical unit 130. In this manner, a semiconductor package can be formed whereby the width of the optical unit 130 in the horizontal direction is less than the width of the package substrate 100 in the horizontal direction, as shown in the cross-sectional drawing of FIG. 3. This leads to heightened integration in the resulting semiconductor package.

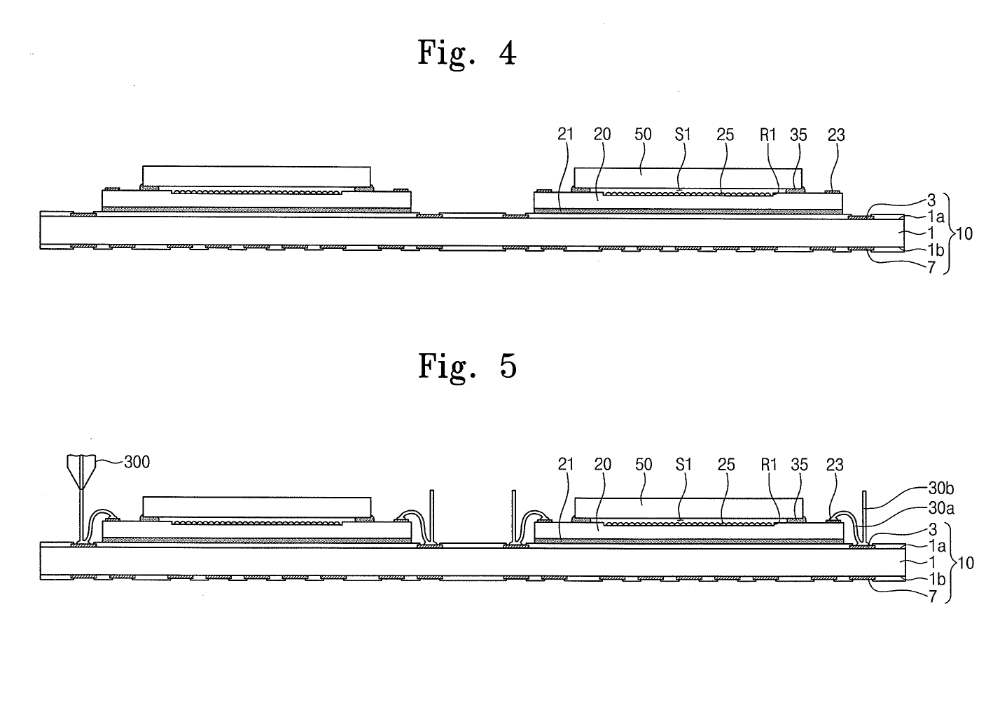

FIGS. 4 through 9 are sectional views sequentially illustrating a process of fabricating the semiconductor package of FIG. 2, in accordance with embodiments of the present inventive concepts.

Referring to FIG. 4, a package substrate 10 is provided. The package substrate 10 may include a substrate body 1 with a first surface 1a and an opposed second surface 1b. The substrate body 1 may be formed of at least one of various insulating materials, such as plastic or ceramics. One or more conductive vias or one or more conductive circuit patterns may be provided in or on the substrate body 1. A first substrate connection terminal 3 may be provided on the first surface 1a, and a second substrate connection terminal 7 may be provided on the second surface 1b. The first surface 1a and the second surface 1b may be covered with protection layers, respectively. In some example embodiments, the package substrate 10 may comprise a printed circuit board.

Referring to FIG. 4, a semiconductor chip 20 may be attached on the package substrate 10 using a first adhesive layer 21. The first adhesive layer 21 may comprise a double-sided tape, or other suitable bonding material. In example embodiments, the semiconductor chip 20 may comprise an image sensor chip. The semiconductor chip 20 may include a pixel area PA and an edge area EA. The pixel area PA may be formed to include a recess region R1 provided with a micro lens array 25. Peripheral circuits may be formed on the edge area EA. A chip connection terminal 23 may be formed on the edge area EA of the semiconductor chip 20.

A transparent substrate 50 may be attached on the semiconductor chip 20 using a second adhesive layer 35. In example embodiments, the transparent substrate 50 may be formed to cover the pixel area PA and expose the chip connection terminal 23. The second adhesive layer 35 may include a photo-sensitive adhesive polymer, a thermo-setting polymer, and/or an epoxy-based mixture.

Referring to FIG. 5, a wire bonding process may be performed to form a first interconnection 30a and a second interconnection 30b. The wire bonding process may be performed by forming a tiny ball of gold or copper on each of the chip connection terminal 23 and the first substrate connection terminal 3 and then forming the interconnections 30a and 30b contacting the tiny ball. In example embodiments, the first interconnection 30a may be formed to connect the chip connection terminal 23 with the first substrate connection terminal 3, and the second interconnection 30b may be formed to extend upward from the first substrate connection terminal 3. Here, a capillary tube 300 may be used to form the first and second interconnections 30a and 30b. For example, the capillary tube 300 may be moved from the chip connection terminal 23 to the first substrate connection terminal 3 to form the first interconnection 30a, and then, be immediately moved upward to form the second interconnection 30b. The second interconnection 30b may be formed to have a top surface that is equivalent to or higher than that of the transparent substrate 50. Since the first and second interconnections 30a and 30b are formed using a wire bonding process, the first and second interconnections 30a and 30b may be formed in such a way that portions being in contact with the chip connection terminal 23 and the first substrate connection terminal 3 are wider than line portions thereof.

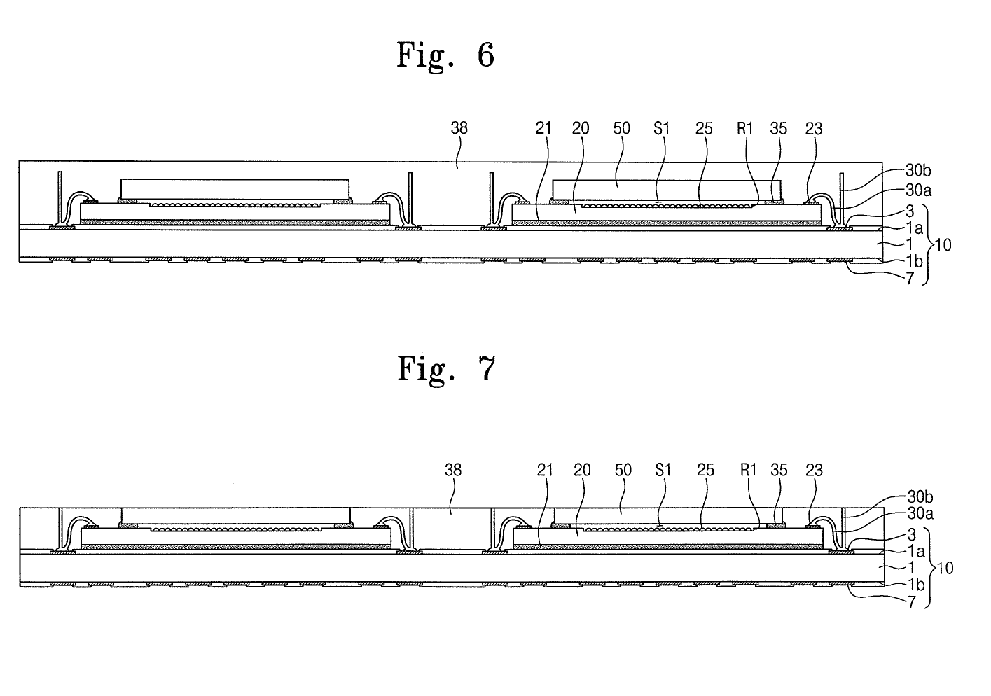

Referring to FIG. 6, a mold layer 38 may be formed on the package substrate 10. For example, an epoxy resin solution may be dropped to cover the package substrate 10, and then be cured to form the mold layer 38. In some embodiments, the mold layer comprises an insulating material. In this sense, the mold layer can be described as an insulating layer. In some embodiments, the mold layer 38 may be formed to have a top surface that is higher than that of the second interconnection 30b. In some embodiments, the mold layer 38 may be formed to have a top surface that is higher than that of the transparent substrate 50.

Referring to FIG. 7, a polishing process (e.g., a chemical-mechanical polishing process) may be performed to remove partially top portions of the mold layer 38 and the transparent substrate 50. Also, top portions of the second interconnection 30b may also be removed. Accordingly, the mold layer 38 and the transparent substrate 50 may have the top surfaces that are flat and coplanar with each other. Top portions of the second interconnection 30b, may also be plat and coplanar with the mold layer 38 and the transparent substrate 50.

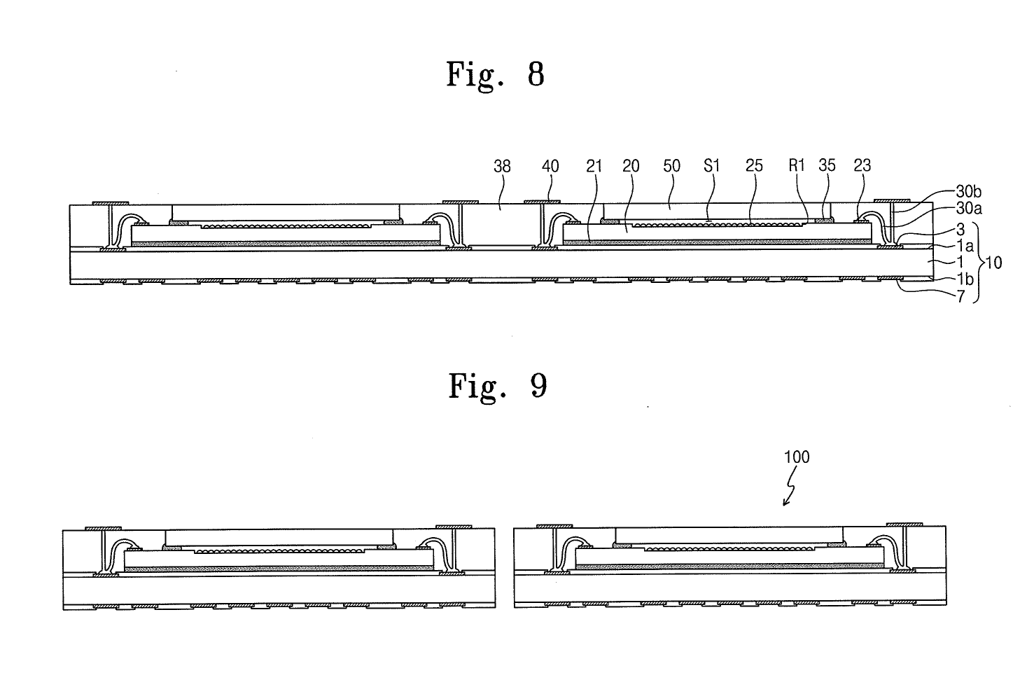

Referring to FIG. 8, a redistribution pattern 40 may be formed on the mold layer 38 and connected to the second interconnection 30b.

Referring to FIG. 9, solder bumps 55 (not shown) may optionally be attached to the second substrate connection terminal 7. A singulation process cutting or dicing the mold layer 38 and the package substrate 10 between the semiconductor chips 20 may be accomplished to form individually separated semiconductor packages 100.

According to the first embodiment of the inventive concepts, the second interconnection 30b may be formed by a simple wiring process, and the semiconductor package 100 can be configured to have improved routability.

### Second Embodiment

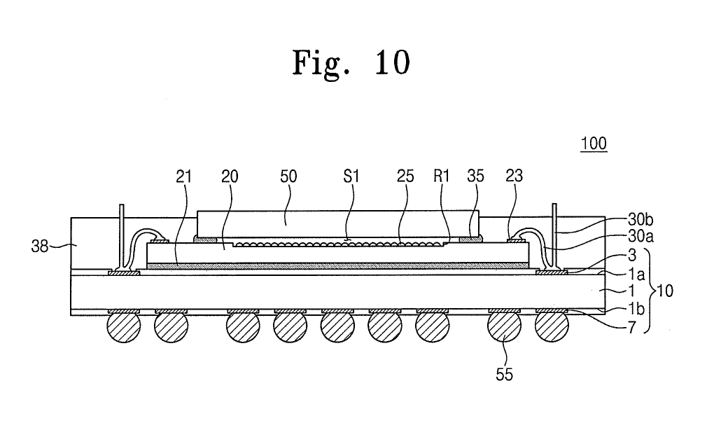

FIG. 10 is a sectional view illustrating a semiconductor package according to a second embodiment of the inventive concepts.

Referring to FIG. 10, in a semiconductor package 101 according to the second embodiment, the mold layer 38 may be formed to have a top surface that is lower than that of the transparent substrate 50 and is higher than a bottom surface of the transparent substrate 50. The top surface of the second interconnection 30b may be higher than that of the mold layer 38. In example embodiments, the semiconductor package 101 may be configured to not include the redistribution pattern 40 of FIG. 2. Beyond this distinction, the semiconductor package 101 may be configured to have substantially the same technical features as those of the semiconductor package 100 of the first embodiment.

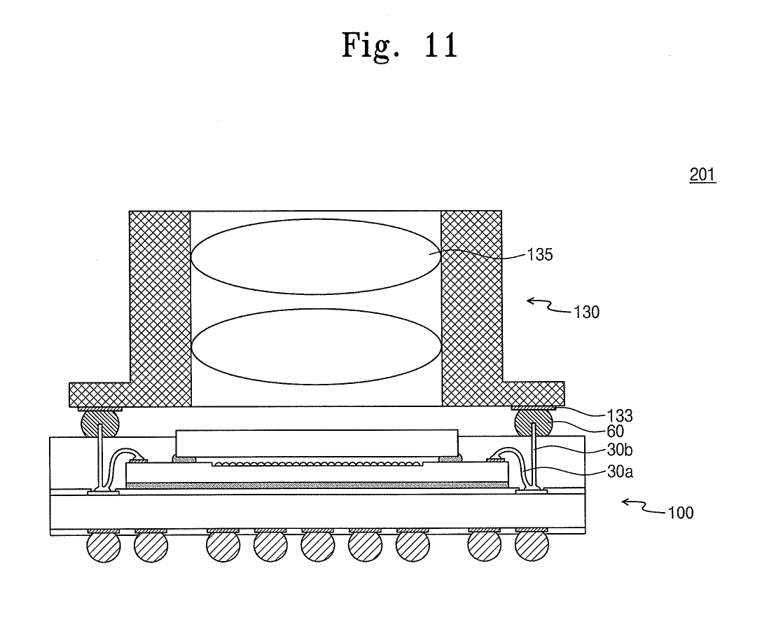

FIG. 11 is a sectional view of an electronic device including the semiconductor package of FIG. 10.

Referring to FIG. 11, in an electronic device 201 according to the second embodiment, the second interconnection 30b may be inserted into the solder bump 60. In other words, the solder bump 60 may be formed to cover top and side surfaces of a portion of the second interconnection 30b protruding from the mold layer 38. Beyond this distinction, the electronic device 201 may be configured to have substantially the same or similar technical features as those of the electronic device 200 described with reference to FIG. 3.

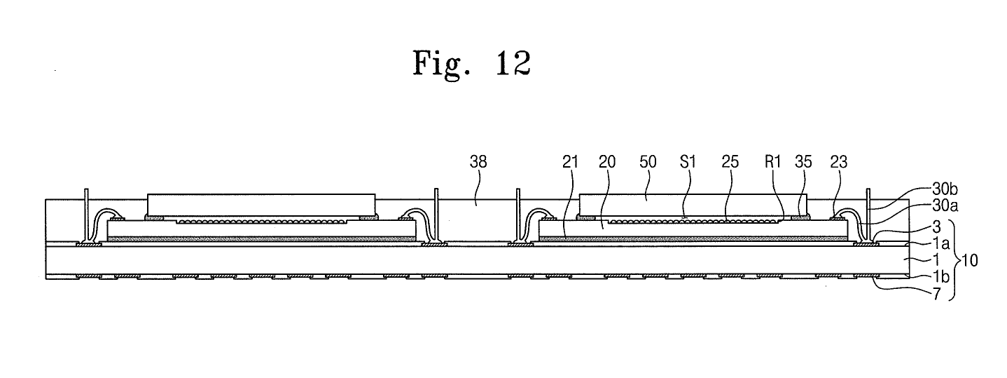

FIG. 12 is a sectional view illustrating a process of fabricating the semiconductor package of FIG. 10.

Referring to FIG. 12, after the formation of the first and second interconnections 30a and 30b as shown in FIG. 5, the epoxy resin solution for the mold layer 38 may be removed in such a manner that a side surface of the transparent substrate 50 is thereby partially covered with the epoxy resin solution. Thereafter, the epoxy resin solution may be cured to form the mold layer 38. The subsequent processes may be performed in the same or similar manner as those of the first embodiment.

### Third Embodiment

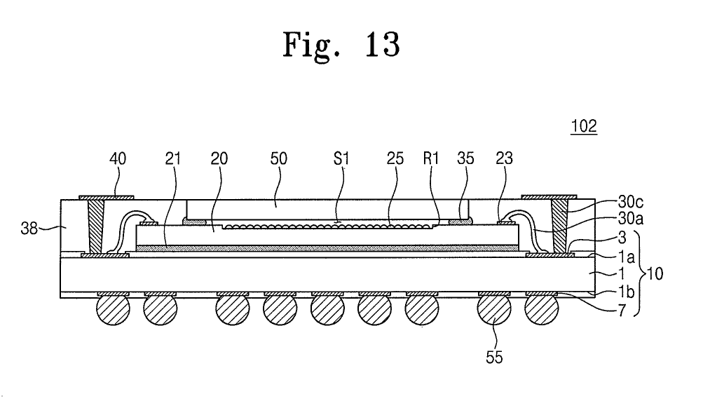

FIG. 13 is a sectional view illustrating a semiconductor package according to a third embodiment of the inventive concepts.

Referring to FIG. 13, in a semiconductor package 102 according to the third embodiment, the second interconnection 30c may be formed in the form of an interconnect comprising a through-mold via, rather than a bonding interconnection. In this case, a bottom surface of the second interconnection 30c may be formed to have a width that is substantially equivalent to or smaller than that of a top surface thereof. The formation of the semiconductor package 102 may include forming a first interconnection 30a using a wire bonding technique, forming a mold layer 38, forming a through-hole for example using a laser to penetrate the mold layer 38 and to expose the first substrate connection terminal 3. The through hole is then filled with a conductive layer to form the second interconnection 30c. In some embodiments, the second interconnection 30c comprising the through-mold via comprises a material that is different from that of the first interconnection 30a. Other than the different configuration of the through-mold-via, the semiconductor package 102 may be formed using substantially the same method as those of the other embodiments disclosed herein and have substantially the same or similar technical features as those of the other embodiments.

### Fourth Embodiment

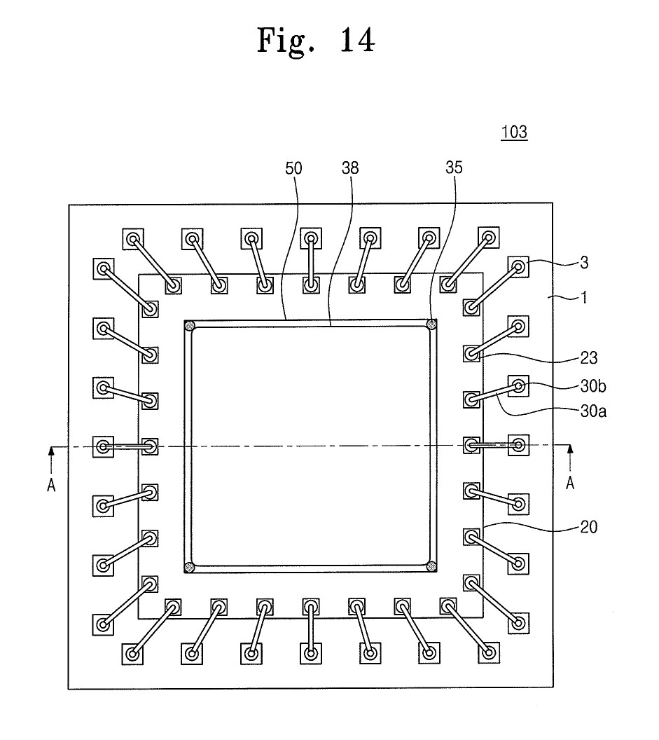

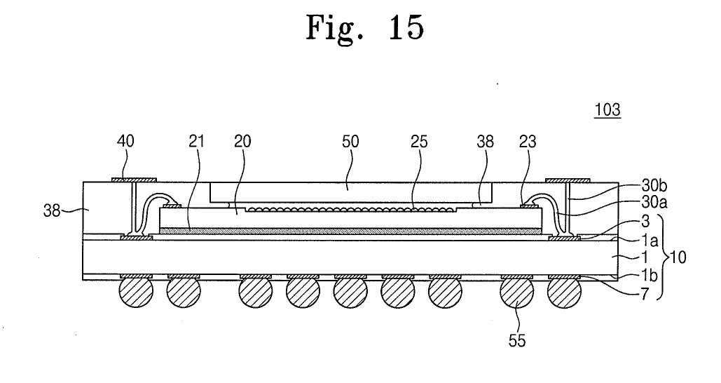

FIG. 14 is a plan view illustrating a semiconductor package according to a fourth embodiment of the inventive concepts. FIG. 15 is a sectional view taken along a line A-A of FIG. 14.

Referring to FIGS. 14 and 15, in a semiconductor package 103 according to the fourth embodiment, the second adhesive layer 35 may be formed adjacent to corners of the transparent substrate 50, rather along a side surface of the transparent substrate 50. In example embodiments, the mold layer 38 may extend partially below a side edge of the transparent substrate 50. Excepting this difference, the semiconductor package 103 may be formed using substantially the same method as those of the first embodiment and have substantially the same or similar technical features as those of the first embodiment.

### Fifth Embodiment

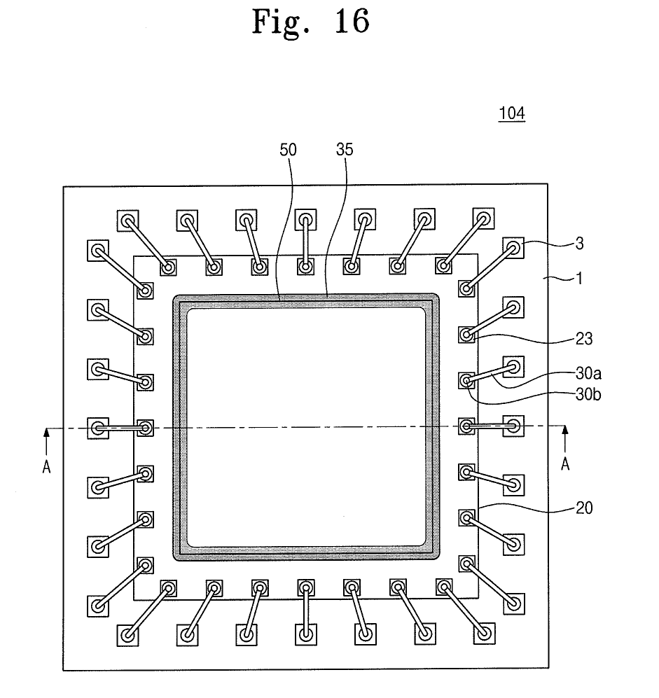

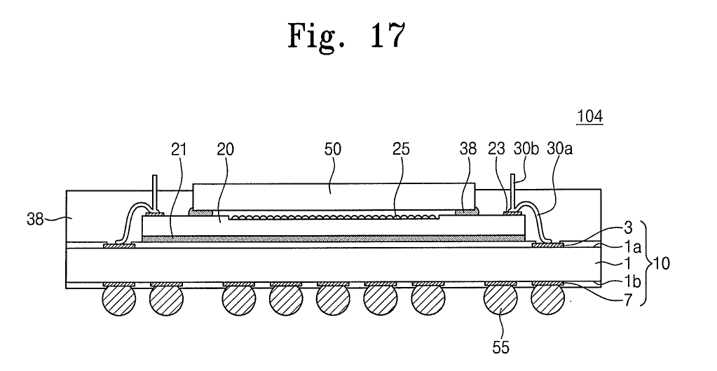

FIG. 16 is a plan view illustrating a semiconductor package according to a fifth embodiment of the inventive concepts. FIG. 17 is a sectional view taken along line A-A of FIG. 16.

Referring to FIGS. 16 and 17, in a semiconductor package 104 according to the fifth embodiment, the second interconnection 30b may be provided on the chip connection terminal 23, or chip pad, rather than on on the first substrate connection terminal 3, or package pad. Otherwise, the semiconductor package 104 may be configured to have substantially the same or similar technical features as those of the semiconductor package 101 of the other embodiments described herein.

### Sixth Embodiment

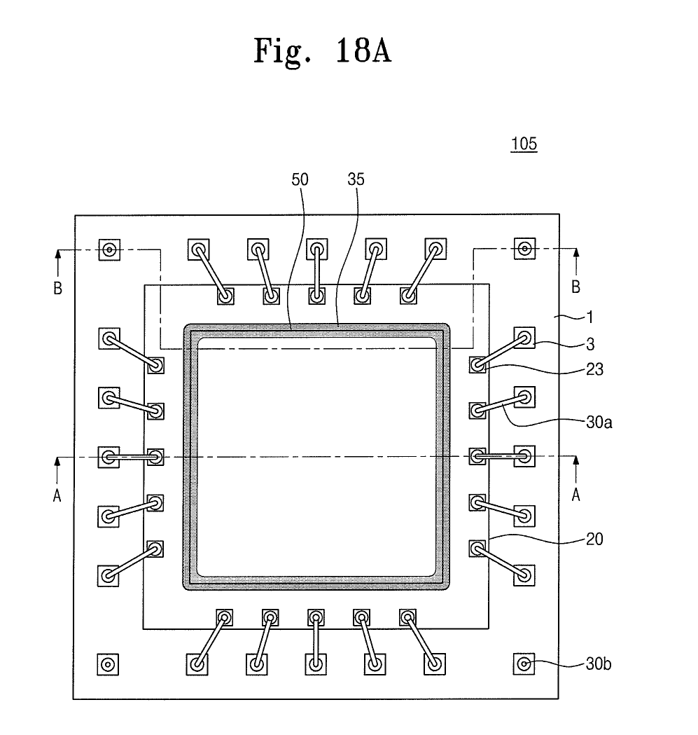

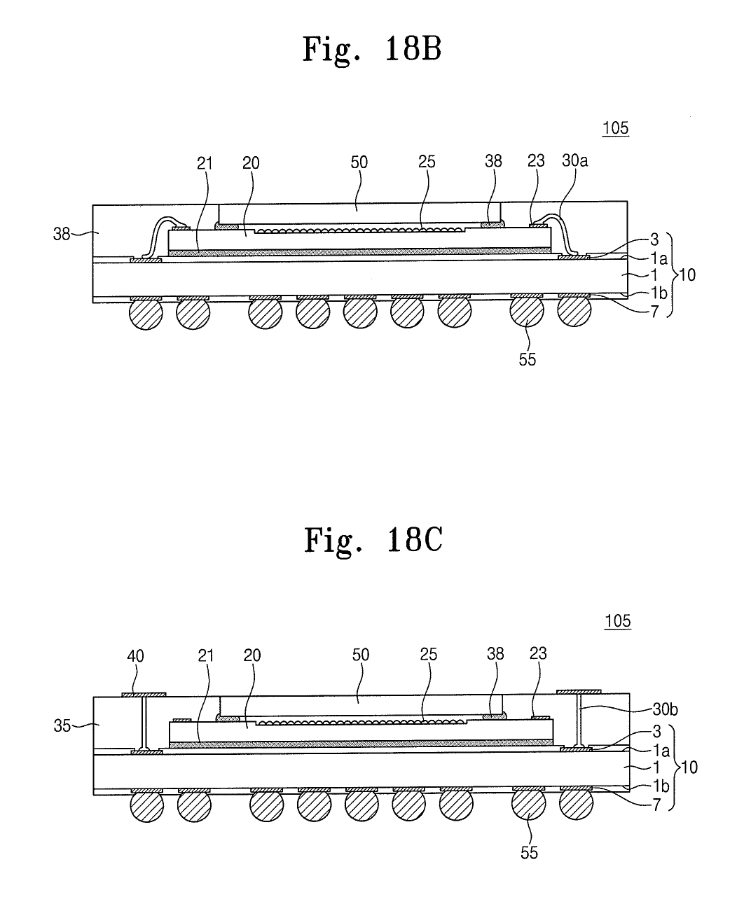

FIG. 18A is a plan view illustrating a semiconductor package according to a sixth embodiment of the inventive concepts. FIGS. 18B and 18C are sectional views taken along lines A-A and B-B of FIG. 18A, respectively.

Referring to FIGS. 18A, 18B, and 18C, in a semiconductor package 105 according to the sixth embodiment, the first interconnection 30a may be provided to connect the first substrate connection terminal 3 to the chip connection terminal 23. The second interconnection 30b may be spaced apart from the first substrate connection terminal 3 in contact with the first interconnection 30a and provided on another of the first substrate connection terminals 3 to penetrate the mold layer 38. The first substrate connection terminals 3 in contact with the second interconnections 30b may be provided in the regions of the four corners of the package substrate 10. Otherwise, the semiconductor package 105 may be configured to have substantially the same or similar technical features as those of the semiconductor package 100 of the other embodiments described herein.

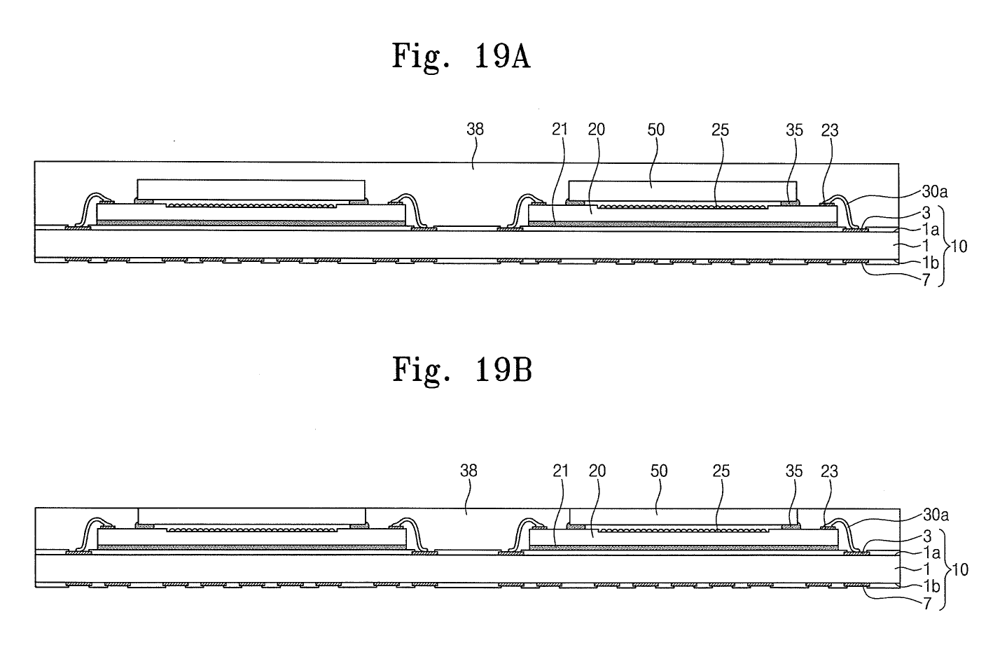

FIGS. 19A and 19B are sectional views illustrating a process of fabricating the semiconductor package 105 of FIG. 18B.

Referring to FIG. 19A, the semiconductor chip 20 may be mounted on the package substrate 10 using the first interconnection 30a, and the transparent substrate 50 may be attached on the semiconductor chip 20. In example embodiments, the first interconnection 30a may be formed using a wire bonding technique. Thereafter, the mold layer 38 may be formed to cover the transparent substrate 50, the semiconductor chip 20, and the package substrate 10. In example embodiments, a top portion of the first interconnection 30a may not be exposed, as shown in FIG. 19B. Although not shown in FIG. 19A, the second interconnection 30b of FIG. 18C may be formed before the formation of the mold layer 38.

Referring to FIG. 19B, a polishing process may be performed to remove at least a portion of the mold layer 38 and thereby expose a top surface of the transparent substrate 50. In example embodiments, a top portion of the transparent substrate 50 may be partially polished and removed. The top portion of the first interconnection 30a may not be exposed, after the polishing process. Although not shown in FIG. 19B, the top surface of the second interconnection 30b may be exposed by the polishing process. Alternatively, a top portion of the second interconnection 30b may be partially removed by the polishing process.

The subsequent processes may be performed in the same or similar manner as those of the other embodiments described herein.

Manufacturability of the semiconductor package can be greatly improved by using the methods described herein, in which the mold layer 38 and the transparent substrate 50 are polished following the molding process.

### Seventh Embodiment

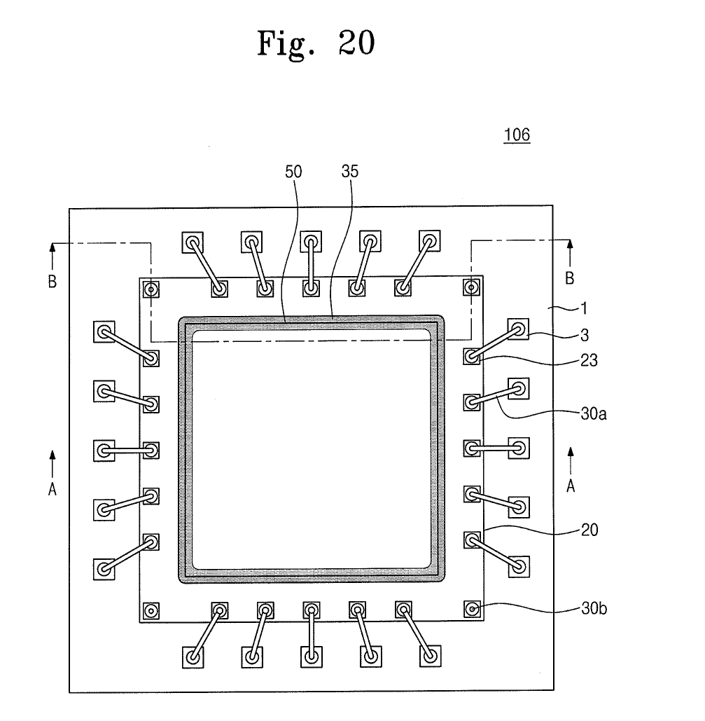

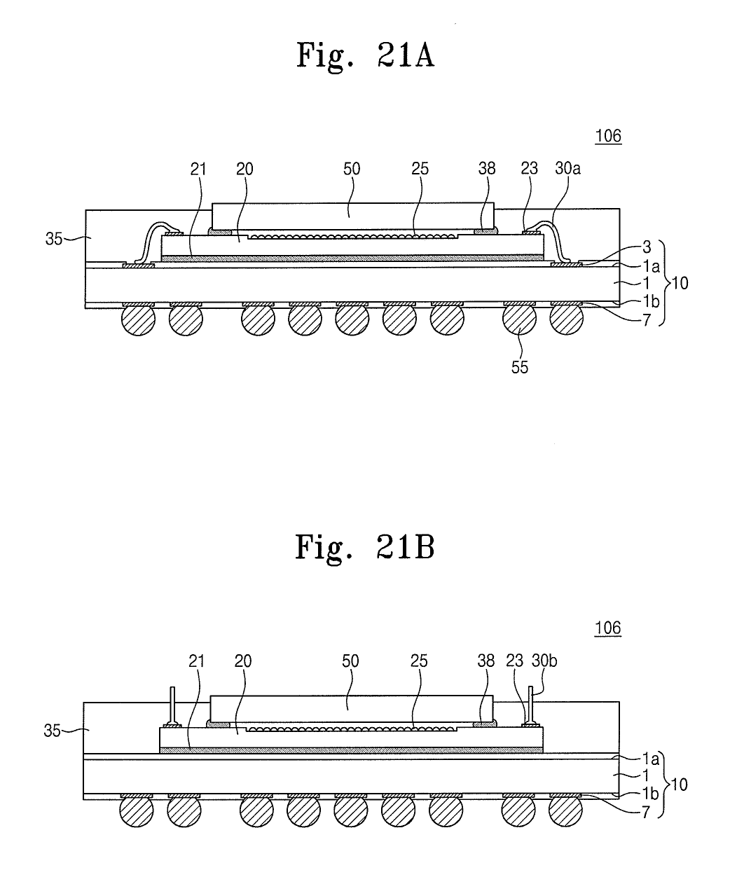

FIG. 20 is a plan view illustrating a semiconductor package according to a seventh embodiment of the inventive concepts. FIGS. 21A and 21B are sectional views taken along lines A-A and C-C of FIG. 20, respectively.

Referring to FIGS. 20, 21A, and 21B, in a semiconductor package 106 according to the seventh embodiment, the first interconnection 30a may be provided to connect the first substrate connection terminal 3 to the chip connection terminal 23. The second interconnection 30b may be spaced apart from the chip connection terminal 23 in contact with the first interconnection 30a and be provided on another of the chip connection terminals 23 to penetrate the mold layer 38. The chip connection terminals 23 in contact with the second interconnections 30b may be provided adjacent to four corners of the semiconductor chip 20. Setting aside this distinction, the semiconductor package 106 may be configured to have substantially the same or similar technical features as those of the semiconductor package 101 of the second embodiment.

### Eighth Embodiment

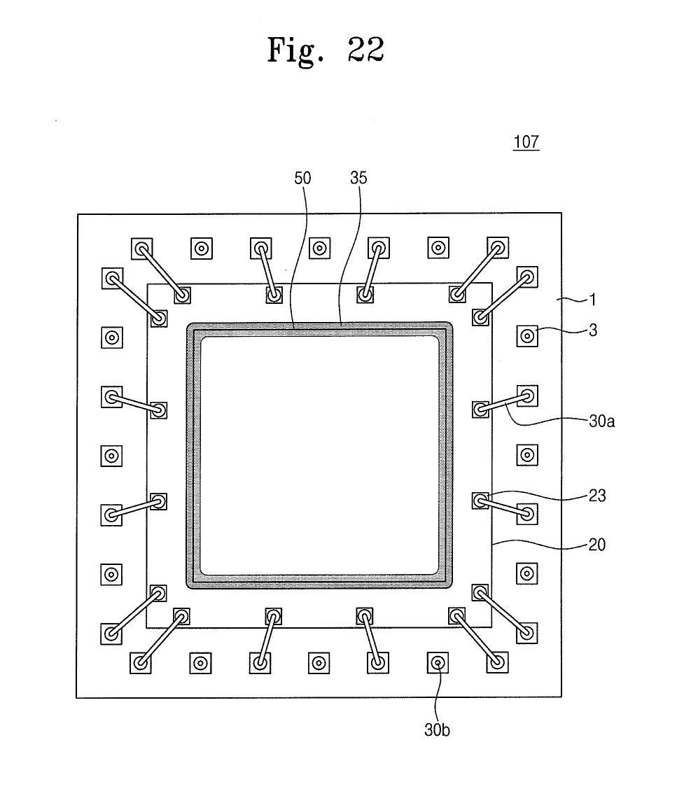

FIG. 22 is a plan view illustrating a semiconductor package according to an eighth embodiment of the inventive concepts.

Referring to FIG. 22, in a semiconductor package 107 according to the eighth embodiment, the first interconnection 30a may be provided to connect the first substrate connection terminal 3 to the chip connection terminal 23. The second interconnection 30b may be spaced apart from the first substrate connection terminal 3 in contact with the first interconnection 30a and provided on another of the first substrate connection terminals 3 to penetrate the mold layer 38. The first interconnections 30a and the second interconnections 30b may be provided in an alternating arrangement, for example as shown. Otherwise, the semiconductor package 107 may be configured to have substantially the same or similar technical features as those of the semiconductor package 105 of the sixth embodiment.

### Ninth Embodiment

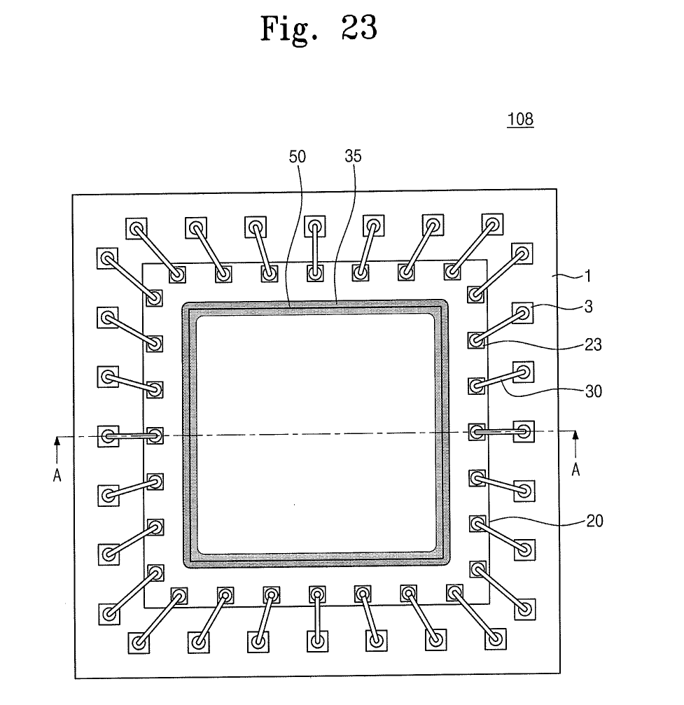

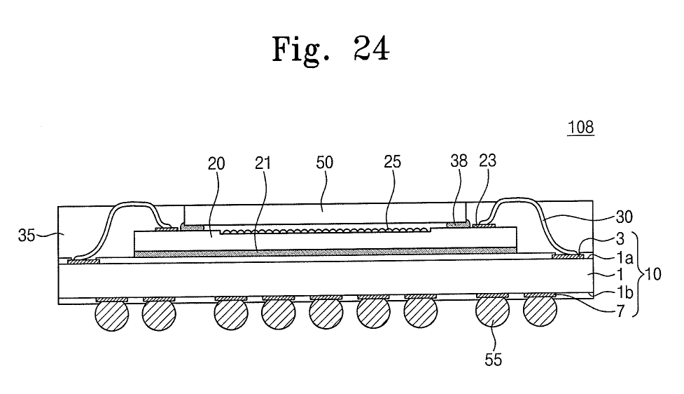

FIG. 23 is a plan view illustrating a semiconductor package according to a ninth embodiment of the inventive concepts. FIG. 24 is a sectional view taken along a line A-A of FIG. 23.

Referring to FIGS. 23 and 24, in a semiconductor package 108 according to the ninth embodiment, the first substrate connection terminal 3 may be connected to the chip connection terminal 23 using an interconnection 30. The interconnection 30 may comprise a metal wire (e.g., of gold or copper), which may be formed using a wire bonding technique. The interconnection 30 may have a top portion that is at a vertical position that is same as or greater than the vertical position of the top surface of the mold layer 38. In this manner, a portion of the bonding wire is exposed above a top portion of the mold layer 38. In example embodiments, the interconnection 30 may be formed in such a way that there is no space between it and the mold layer 38. For example, a bottom surface of the top portion of the interconnection 30 may be in direct contact with the top surface of the mold layer 38.

The formation of the semiconductor package 108 may include forming the interconnection 30 using a wire bonding technique, and forming an epoxy resin solution for the mold layer 38 in such a way that the epoxy resin solution is in contact with at least the bottom surface of the top portion of the interconnection 30 but not cover the top portion of the interconnection 30. This makes it possible to omit the polishing process of the first embodiment.

### Tenth Embodiment

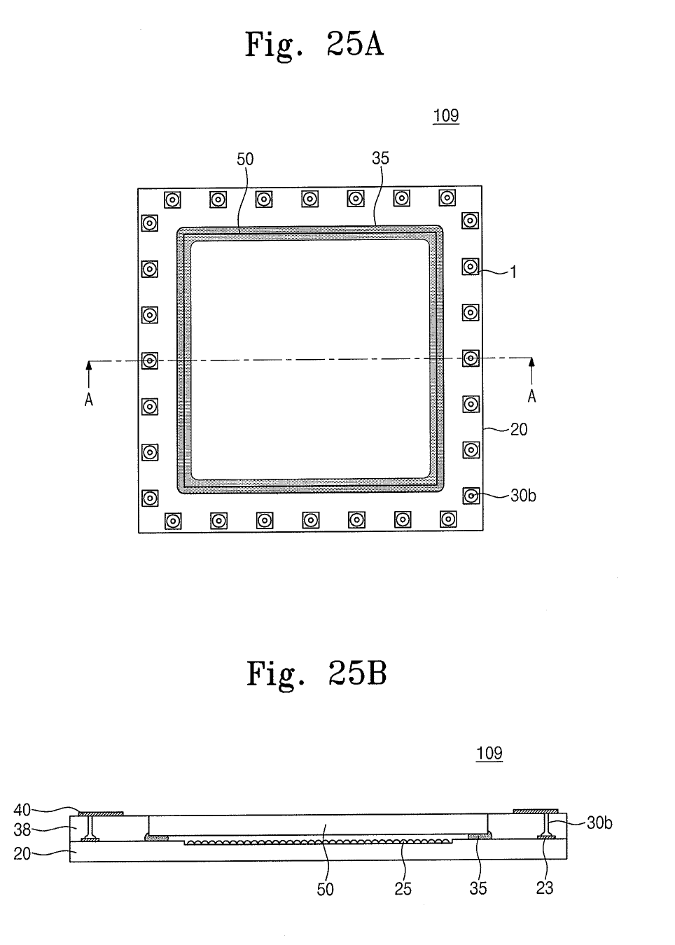

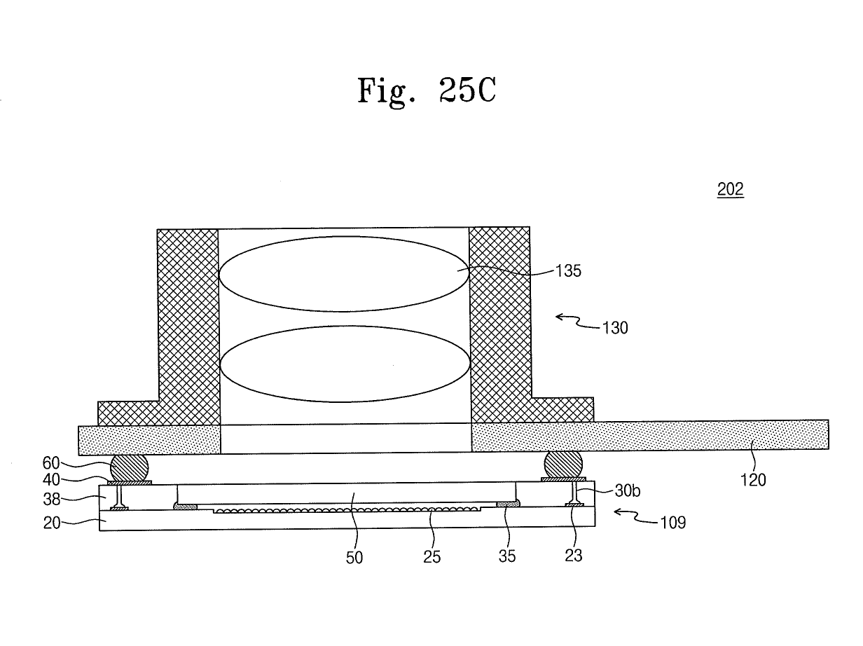

FIG. 25A is a plan view illustrating a semiconductor package according to a tenth embodiment of the inventive concepts. FIG. 25B is a sectional view taken along line A-A of FIG. 25A.

Referring to FIGS. 25A and 25B, a semiconductor package 109 according to the tenth embodiment may be formed using a wafer level package (WLP) technology. The semiconductor package 109 may be configured without the package substrate 10. The transparent substrate 50 may be attached on the semiconductor chip 20 using the adhesive layer 35. The interconnection 30b may be formed on the chip connection terminal 23 using a wire bonding technique. Thereafter, the mold layer 38 may be formed. a polishing process may be performed to remove partially the mold layer 38, the interconnection 30b, and the transparent substrate 50. Next, the redistribution pattern 40 may be formed to be in contact with the top surface of the interconnection 30b.

FIG. 25C is a sectional view of an electronic device with a semiconductor package of FIG. 25B.

Referring to FIG. 25C, in the electronic device 203 according to the tenth embodiment, the optical unit 130 may be mounted on a top surface of a circuit substrate 120, and the semiconductor package 109 may be mounted on a bottom surface of the circuit substrate 120 to be overlapped with the optical unit 130. The circuit substrate 120 may be formed of a rigid or flexible material. The semiconductor package 109 may be directly connected to the optical unit 130, without the circuit substrate 120 being interposed therebetween.

Other than this distinction, the electronic device may be configured to have substantially the same or similar technical features as that of the other embodiments described herein.

As described above, semiconductor packages and electronic devices can be realized in various manners, based on the inventive concepts. However, example embodiments of the inventive concepts are not necessarily limited thereto.

[Application]

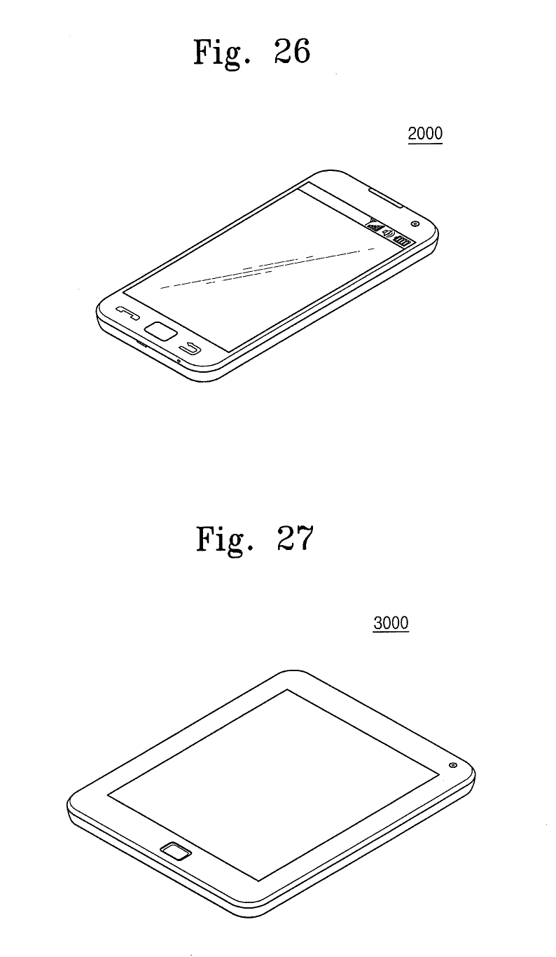

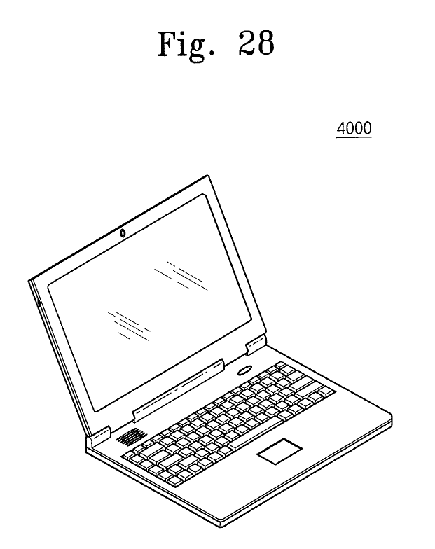

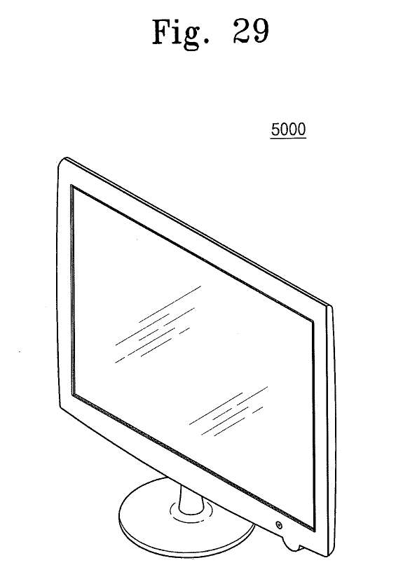

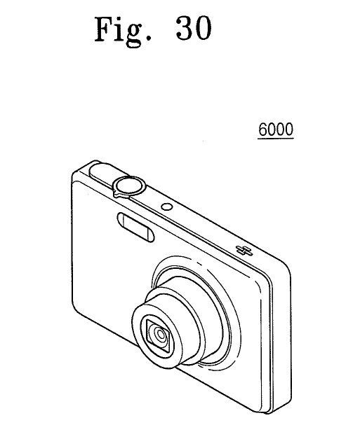

FIGS. 26 through 30 show examples of multimedia devices, for which semiconductor package devices according to example embodiments of the inventive concepts can be employed. Semiconductor package devices 101-109 according to example embodiments of the inventive concepts can be applied to a variety of multimedia devices with an imaging function. For example, the semiconductor package devices 101-109 according to example embodiments of the inventive concepts may be applied to a mobile phone or smart phone 2000 as exemplarily shown in FIG. 26, to a tablet PC or smart tablet PC 3000 as exemplarily shown in FIG. 27, to a laptop computer 4000 as exemplarily shown in FIG. 28, to a television set or smart television set 5000 as exemplarily shown in FIG. 29, and to a digital camera or digital camcorder 6000 as exemplarily shown in FIG. 30.

According to example embodiments of the inventive concepts, a semiconductor package may include an interconnection, which may be directly formed in an upwardly oriented direction from a top surface of a semiconductor chip and/or a package substrate using a wire bonding technique. This makes it possible to improve routability of the semiconductor package. Further, this makes it possible to connect the interconnection directly to optical unit, and thus, a total size of the semiconductor package including the optical unit can be reduced.

While example embodiments of the inventive concepts have been particularly shown and described, it will be understood by one of ordinary skill in the art that variations in form and detail may be made therein without departing from the spirit and scope of the attached claims.

1. A semiconductor package comprising:
a package substrate including a package pad, the package pad being conductive; a semiconductor chip on the package substrate including a chip pad, the chip pad being conductive, the semiconductor chip extending in a horizontal direction of extension;
a transparent substrate on the semiconductor chip;
an insulative layer at sides of the transparent substrate and on the package substrate; and
a vertical interconnect through the insulative layer, the vertical interconnect in contact with at least one of the package pad and chip pad, the vertical interconnect extending in a substantially vertical direction of extension relative to the horizontal direction of extension of the semiconductor chip.

2. (canceled)

3. The semiconductor package of claim 1 wherein a top of the insulative layer is lower in height relative to the package substrate than a top of the transparent substrate.

4. The semiconductor package of claim 3 wherein a top portion of the vertical interconnect is greater in height relative to the package substrate than the top of the insulative layer.

5. (canceled)

6. The semiconductor package of claim 1 wherein the vertical interconnect comprises a conductive via.

7. The semiconductor package of claim 1 wherein the vertical interconnect comprises a bonding wire.

8. (canceled)

9. The semiconductor package of claim 1 wherein portions of the mold layer are positioned between the transparent substrate and the semiconductor chip.

10-12. (canceled)

13. The semiconductor package of claim 1 wherein the vertical interconnect is in direct contact with the chip pad.

14-17. (canceled)

18. The semiconductor package of claim 1 further comprising a bonding wire that extends between the package pad and the chip pad and wherein a portion of the bonding wire is exposed above a top portion of the insulative layer.

19. The semiconductor package of claim 1 wherein the insulative layer comprises a package mold layer

20. (canceled)

21. A semiconductor package comprising:
a package substrate including a package pad, the package pad being conductive;
a semiconductor chip on the package substrate including a chip pad, the chip pad being conductive;
a transparent substrate on the semiconductor chip;
an insulative layer at sides of the transparent substrate and on the package substrate; and
an interconnect through the insulative layer, the interconnect in contact with at least one of the package pad and chip pad and spaced apart from the transparent substrate, the interconnect extending to a top of the insulative layer.

22. The semiconductor package of claim 21 wherein a portion of the interconnect extends above a top of the insulative layer.

23. The semiconductor package of claim 21 wherein a portion of the insulative layer lies between the interconnect and the transparent substrate

24. The semiconductor package of claim 21 wherein the semiconductor chip extends in a horizontal direction of extension and wherein the interconnect extends in a substantially vertical direction of extension relative to the horizontal direction of extension of the semiconductor chip.

25-28. (canceled)

29. The semiconductor package of claim 21 wherein the interconnect comprises a conductive via.

30-31. (canceled)

32. The semiconductor package of claim 21 wherein portions of the mold layer are positioned between the transparent substrate and the semiconductor chip.

33-35. (canceled)

36. The semiconductor package of claim 21 wherein the interconnect is in direct contact with the chip pad.

37-51. (canceled)

52. A semiconductor package comprising:
a package substrate including a plurality of package pads, the package pads being conductive;
a semiconductor chip on the package substrate including a plurality of chip pads, the chip pads being conductive;
a transparent substrate on the semiconductor chip;
an insulative layer at sides of the transparent substrate and on the package substrate;
a plurality of bonding wires, each bonding wire connected between one of the chip pads and a corresponding one of the package pads; and
a plurality of interconnects through the insulative layer, each interconnect in contact with at least one of the package pads and chip pads, wherein the interconnects comprise a material that is different than the bonding wires.

53. The semiconductor package of claim 52 wherein the plurality of interconnects are spaced apart from the transparent substrate.

54. The semiconductor package of claim 52 wherein the plurality of interconnects extend to a top of the insulative layer

55. The semiconductor package of claim 52 wherein a portion of the interconnect extends above a top of the insulative layer.

56. The semiconductor package of claim 52 wherein a portion of the insulative layer lies between the interconnect and the transparent substrate

57-74. (canceled)
